(19) United States
(12) Patent Application Publication
(10) Pub. No.: US 2003/0233606 A1
(43) Pub. Date: Dec. 18, 2003

(54) Test facilitation circuit

(75) Inventor: Yasuhiro Mabuchi, Tokyo (JP)

Correspondence Address: McDermott, Will & Emery, 600 13th Street, N.W., Washington, DC, 20005-3096, US

(73) Assignee: MITSUBISHI DENKI KABUSHIKI KAISHA

(21) Appl. No.: 10/316,083

(22) Filed: Dec. 11, 2002

(30) Foreign Application Priority Data
Jun. 12, 2002 (JP) 2002-171866

(51) Int. Cl. G01R 31/28

(52) U.S. Cl. 714/724

(57) ABSTRACT

A testing apparatus is configured by using test facilitation circuits and a tester, and expectation data are output from the tester, whereby the pins of the tester corresponding to the output-dedicated terminals of DUTs can be shared by the DUTs. Even if the number of DUTs is increased to three or more, the existing pins of the tester corresponding to the output-dedicated terminals of the existing DUTs can still serve for the output-dedicated terminals of new DUTs. Therefore, to increase the simultaneous measurement number L, it is not necessary to increase the number of pins of the tester with the number K of output-dedicated terminals of each DUT as a proportionality constant.

### BACKGROUND OF THE INVENTION

1. Field of the Invention

The present invention relates to a test facilitation circuit etc. In particular, the invention relates to a test facilitation circuit etc. in a testing apparatus that simultaneously tests L (≧2) digital ICs under test each having K (≧1) output terminals.

2. Background Art

FIG. 6 shows a conventional testing apparatus for testing devices under test (DUTs) such as digital ICs. In FIG. 6, reference numeral 80 denotes a first DUT (DUT1), numeral 85 denotes a second DUT (DUT2), and numeral 90 denotes a testing apparatus (tester) for testing the DUT1 80 and DUT2 85. The DUT1 80 has two input-dedicated terminals A-1 and B-1 and four output-dedicated terminals C-1, D-1, E-1, and F-1. The DUT2 85 has two input-dedicated terminals A-2 and B-2 and four output-dedicated terminals C-2, D-2, E-2, and F-2. On the other hand, the tester 90 is equipped with a driver 91 for outputting a signal a as test data to the input-dedicated terminal A-1 of the DUT1 80 and the input-dedicated terminal A-2 of the DUT2 85, a driver 92 for outputting a signal b as test data to the input-dedicated terminal B-1 of the DUT1 80 and the input-dedicated terminal B-2 of the DUT2 85, a comparator 93 for receiving a signal c-1 that is output data from the output-dedicated terminal C-1 of the DUT1 80, a comparator 94 for receiving a signal d-1 that is output data from the output-dedicated terminal D-1 of the DUT1 80, a comparator 95 for receiving a signal e-1 that is output data from the output-dedicated terminal E-1 of the DUT1 80, and a comparator 96 for receiving a signal f-1 that is output data from the output-dedicated terminal F-1 of the DUT1 80. The tester 90 is further equipped with a comparator 97 for receiving a signal c-2 that is output data from the output-dedicated terminal C-2 of the DUT2 85, a comparator 98 for receiving a signal d-2 that is output data from the output-dedicated terminal D-2 of the DUT2 85, a comparator 99 for receiving a signal e-2 that is output data from the output-dedicated terminal E-2 of the DUT2 85, and a comparator 100 for receiving a signal f-2 that is output data from the output-dedicated terminal F-2 of the DUT2 85.

As shown in FIG. 6, in the conventional testing apparatus (tester 90), the input signals a and b that are used in a test are common to the DUT1 80 and DUT2 85. Therefore, even if the number of DUTs is three or more, the signals a and b to be input to the DUTs can still be shared by the DUTs.

However, as shown in FIG. 6, in the conventional testing apparatus (tester 90), the signals c-1 to f-1 that are output from the respective output-dedicated terminals C-1 to F-1 of the DUT1 80 and the signals c-2 to f-2 that are output from the respective output-dedicated terminals C-2 to F-2 cannot be commonized because it is necessary for the tester 90 to judge whether each DUT is operating normally.

As described above, in the conventional testing apparatus (tester 90), output signals from respective DUTs cannot be commonized. Therefore, to increase the number of DUTs that can be tested simultaneously (hereinafter referred to as test simultaneous measurement number or simply as simultaneous measurement number), the tester 90 should have pins of a number (e.g., K×L=8 in the case of FIG. 1) that is equal to the number K (e.g., K=4 in each DUT shown in FIG. 1) of DUT-side output-dedicated terminals C-1 etc. multiplied by the simultaneous measurement number L (e.g., L=2 in the case of FIG. 1). That is, there is a problem that to increase the simultaneous measurement number L, the number of pins that the tester 90 should have increases with K as a proportionality constant, resulting in increase in the manufacturing cost of the testing apparatus.

### SUMMARY OF THE INVENTION

The present invention has been made to solve the above problem, and an object of the invention is therefore to provide a test facilitation circuit etc. capable of preventing the number of pins of the tester 90 from increasing with the number K of output-dedicated terminals of each DUT as a proportionality constant in increasing the simultaneous measurement number L.

According to one aspect of the present invention, a test facilitation circuit of a testing apparatus is provided for simultaneously testing L digital ICs each having K output terminals, where L is greater than or equal to 2 and K is greater than or equal to 1. The test facilitation circuit receives K output data that are output from the K respective output terminals of each of the L digital ICs and K expectation data that are output from K respective drivers of a tester that has the K drivers and L comparators, and the test facilitation circuit supplies the L comparators with L judgment results for the output data of the L digital ICs, respectively.

According to another aspect of the present invention, a test facilitation circuit of a testing apparatus is provided for simultaneously testing L digital ICs each having a plurality of input/output terminals, where L is greater than or equal to 2. The test facilitation circuit supplies L judgment results for output data of the L digital ICs to L comparators of a tester, respectively, where the tester has the L comparators, test data output drivers for outputting respective test data, and control signal output drivers for outputting respective control signals to be used for controlling the test data in such a manner that the control signals accompany the respective test data. The test facilitation circuit comprises L units that correspond to the L respective digital ICs. When the control signals are active, each of the L units supplies the input/output terminals of the corresponding one of the digital ICs with the test data that are output from the test data output drivers of the tester; and when the control signals are not active, each of the L units receives output data that are output from the input/output terminals of the corresponding one of the digital ICs, the test data that are output from the test data output drivers of the tester and the control signals that are output from the control signal output drivers of the tester, and supplies a corresponding one of the L comparators with a judgment result for the output data of the corresponding one of the digital ICs.

Other and further objects, features and advantages of the invention will appear more fully from the following description.

### BRIEF DESCRIPTION OF THE DRAWINGS

FIG. 1 shows a testing apparatus according to a first embodiment of the invention for testing devices under test (DUTs) such as digital ICs.

FIG. 2 shows a testing apparatus according to a second embodiment of the invention for testing devices under test (DUTs) such as digital ICs.

FIG. 3 is a timing chart showing with what strobe timing signals are output according to the third embodiment.

FIG. 4 is a timing chart showing timing between a signal that is output from each of the output-dedicated terminals and a signal that is output from the corresponding one of the drivers.

FIG. 5 shows a testing apparatus according to the third embodiment of the invention for testing devices under test (DUTs) such as digital ICs.

FIG. 6 shows a conventional testing apparatus for testing devices under test (DUTs) such as digital ICs.

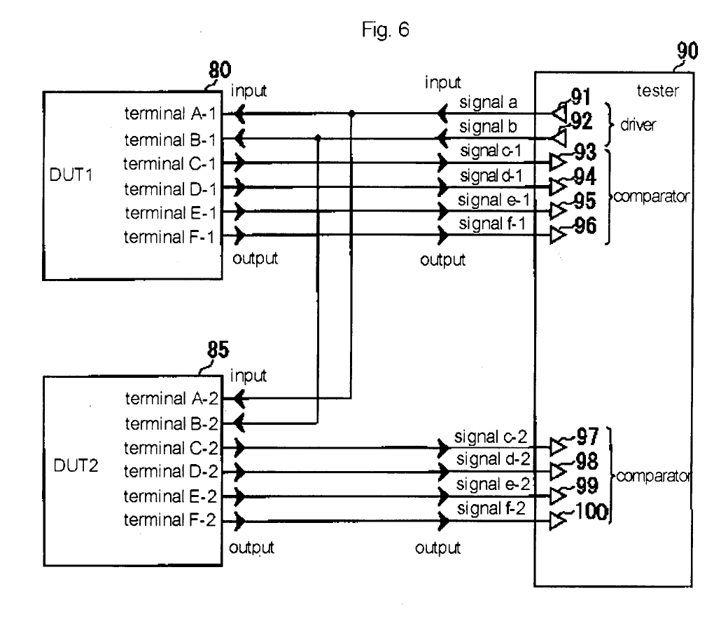

### DETAILED DESCRIPTION OF THE PREFERRED EMBODIMENTS

Embodiments of the present invention will be hereinafter described in detail with reference to the accompanying drawings.

First Embodiment

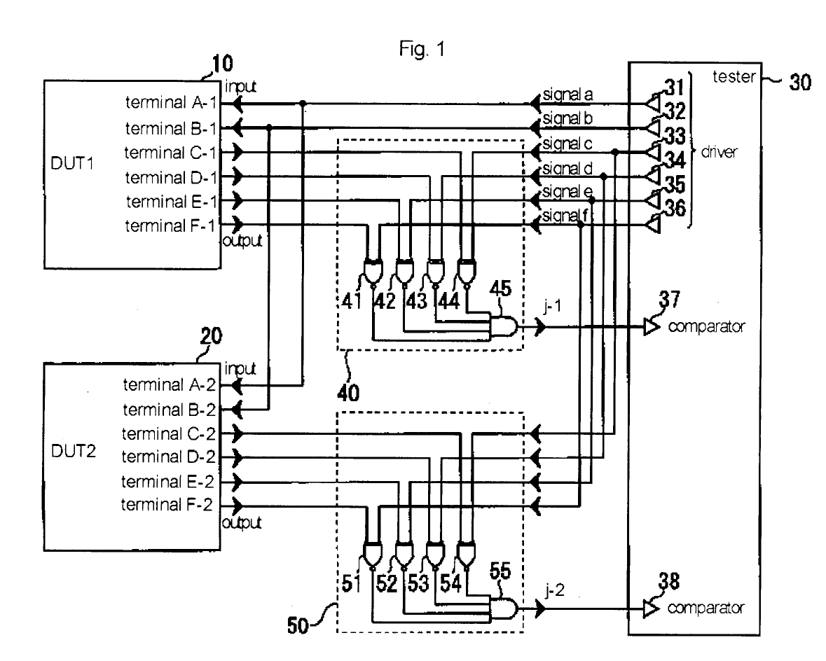

FIG. 1 shows a testing apparatus according to a first embodiment of the invention for testing devices under test (DUTs) such as digital ICs. In FIG. 1, reference numeral 10 denotes a first DUT (DUT1), numeral 20 denotes a second DUT (DUT2), numeral 30 denotes a tester for testing the DUT1 10 and DUT2 20, and numerals 40 and 50 denote test facilitation circuits corresponding to the DUT1 10 and the DUT2 20, respectively. The testing apparatus according to the first embodiment is composed of the tester 30 and the test facilitation circuits 40 and 50.

As shown in FIG. 1, the DUT1 10 has two input-dedicated terminals A-1 and B-1 and four output-dedicated terminals C-1, D-1, E-1, and F-1. The output-dedicated terminals C-1, D-1, E-1, and F-1 of the DUT1 10 are connected to respective exclusive OR circuits 44, 43, 42, and 41 of the test facilitation circuit 40. The DUT2 20 has two input-dedicated terminals A-2 and B-2 and four output-dedicated terminals C-2, D-2, E-2, and F-2. The output-dedicated terminals C-2, D-2, E-2, and F-2 of the DUT2 20 are connected to respective exclusive OR circuits 54, 53, 52, and 51 of the test facilitation circuit 50.

On the other hand, as shown in FIG. 1, the tester 30 is equipped with a driver 31 for outputting, to the input-dedicated terminal A-1 of the DUT1 10 and the input-dedicated terminal A-2 of the DUT2 20, a signal (logical variable) a as test data to be used for testing operation of the DUT1 10 and DUT2 20; a driver 32 for outputting, to the input-dedicated terminal B-1 of the DUT1 10 and the input-dedicated terminal B-2 of the DUT2 20, a signal (logical variable) b as test data for the DUT1 10 and DUT2 20; a driver 33 for outputting, to the exclusive OR circuits 44 and 54 of the respective test facilitation circuits 40 and 50, a signal (logical variable) c as expectation data that is expected as an operation test result of the DUT1 10 and DUT2 20; a driver 34 for outputting, to the exclusive OR circuits 43 and 53 of the respective test facilitation circuits 40 and 50, a signal (logical variable) d as expectation data that is expected for the DUT1 10 and DUT2 20; a driver 35 for outputting, to the exclusive OR circuits 42 and 52 of the respective test facilitation circuits 40 and 50, a signal (logical variable) e as expectation data that is expected for the DUT1 10 and DUT2 20; a driver 36 for outputting, to the exclusive OR circuits 41 and 51 of the respective test facilitation circuits 40 and 50, a signal (logical variable) f as expectation data that is expected for the DUT1 10 and DUT2 20; a comparator 37 for receiving a judgment result j-1 of the test facilitation circuit 40; and a comparator 38 for receiving a judgment result j-2 of the test facilitation circuit 50.

The test facilitation circuit 40 is a circuit for comparing output data of the DUT1 10 with expectation data that are supplied from the tester 30. As shown in FIG. 1, the test facilitation circuit 40 has an AND circuit 45 for calculating the AND of negated outputs of the exclusive OR circuits 41-44. An output of the AND circuit 45, which is supplied to the comparator 37 of the tester 30, is a judgment result (judgment result j-1) of the test facilitation circuit 40 that indicates whether the DUT1 10 is good or no good. Similarly, the test facilitation circuit 50 is a circuit for comparing output data of the DUT2 20 with expectation data that are supplied from the tester 30. As shown in FIG. 1, the test facilitation circuit 50 has an AND circuit 55 for calculating the AND of negated outputs of the exclusive OR circuits 51-54. An output of the AND circuit 55, which is supplied to the comparator 38 of the tester 30, is a judgment result (judgment result j-2) of the test facilitation circuit 50 that indicates whether the DUT2 20 is good or no good.

Next, functions of the testing apparatus including the test facilitation circuits 40 and 50 and the tester 30 will be described. Signals (output data) that are output from the output-dedicated terminals C-1, D-1, E-1, and F-1 of the DUT1 10 are represented by logical variables C1, D1, E1, and F1, respectively. Logical expressions of the negated outputs of the exclusive OR circuits 41-44 are as follows:

[Formula 1]

(Negated output of exclusive OR circuit 41)=\overline{F1⊕f}

(Negated output of exclusive OR circuit 42)=\overline{E1⊕e}

(Negated output of exclusive OR circuit 43)=\overline{D1⊕d}

(Negated output of exclusive OR circuit 44)=\overline{C1⊕c}

In the above logical expressions, symbol “\overline{X}” means the negation of X and symbol “⊕” means exclusive OR.

Therefore, the output (judgment result j-1) of the AND circuit 45 is given by the following Equation (1):

[Formula 2]

(Output (judgment result j-1) of AND circuit 45)=\overline{C1⊕c}·\overline{D1⊕d}·\overline{E1⊕e}·\overline{F1⊕f} (1)

where symbol “·” means AND.

If all the output data of the DUT1 10 coincide with the corresponding expectation data that are output from the tester 30, that is, if C1 =c, D1=d, E1=e, and F1=f, each exclusive OR result of Equation (1) is equal to 0. Therefore, the AND circuit 45 has an output (judgment result j-1) that is given by the following Equation (2):

[Formula 3]

(Output (judgment result j-1) of AND circuit 45)=\overline{0}·\overline{0}·\overline{0}·\overline{0}=1 (2)

Therefore, if all output data of the DUT1 10 coincide with corresponding expectation data that are output from the tester 30, a judgment result j-1 that is equal to 1 is obtained. In other words, if the judgment result j-1 is not equal to 1, one can recognize that a certain failure has occurred in the DUT1 10. The judgment result j-2 of the test facilitation circuit 50 is similar to the judgment result j-1 of the test facilitation circuit 40 and hence will not be described.

As described above, according to the first embodiment, the testing apparatus (i.e., the test facilitation circuits 40 and 50 and the tester 30) is configured as shown in FIG. 1 and expectation data are output from the tester 30, whereby the pins of the tester 30 corresponding to the output-dedicated terminals of the DUT1 10 and DUT2 20, that is, the pins of the drivers 33-36, can be shared by the DUT1 10 and DUT2 20. Even if the number of DUTs is increased to three or more, the existing pins of the tester 30 corresponding to the output-dedicated terminals of the DUT1 10 and DUT2 20, that is, the pins of the drivers 33-36, can still serve for the output-dedicated terminals of new DUTs. Therefore, to increase the simultaneous measurement number L (L=2 in FIG. 1), it is not necessary to increase the number of pins of the tester 30 with the number K of output-dedicated terminals of each DUT (K=4 in FIG. 1) as a proportionality constant.

Although in the above embodiment the test facilitation circuits 40 and 50 are located outside the DUT1 10 and DUT2 20, they may be incorporated in the DUT1 10 and the DUT2 20 as test facilitation design circuits DFTs (design for test), respectively. Alternatively, the test facilitation circuits 40 and 50 may be provided, as a BOST (built out self test) circuit, on a DUT board for interfacing between the tester 30 and the DUT1 10 and DUT2 20.

Second Embodiment

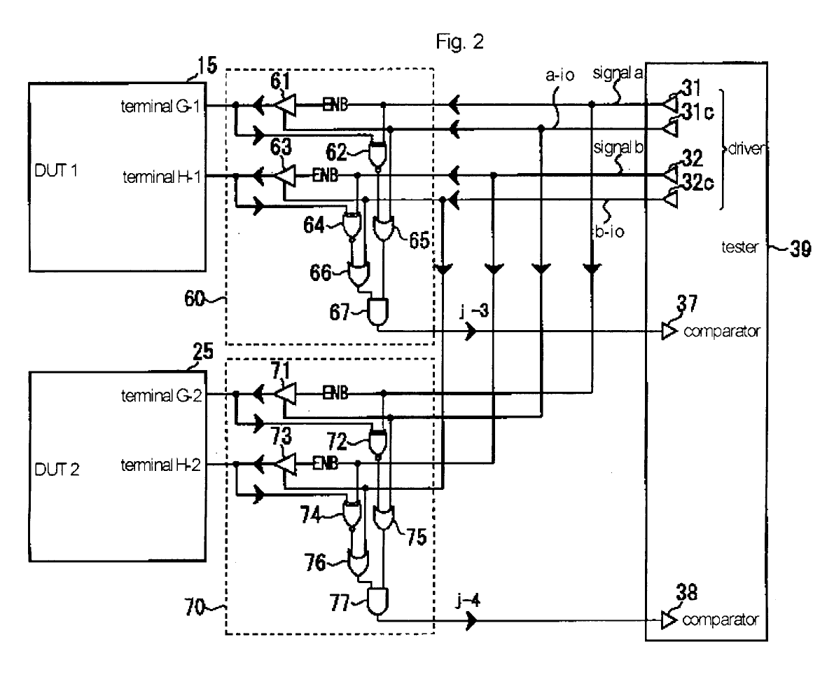

FIG. 2 shows a testing apparatus according to a second embodiment of the invention for testing devices under test (DUTs) such as digital ICs. In FIG. 2, reference numeral 15 denotes a first DUT (DUT1), numeral 25 denotes a second DUT (DUT2), numeral 39 denotes a tester for testing the DUT1 15 and DUT2 25, and numerals 60 and 70 denote test facilitation circuits corresponding to the DUT1 15 and the DUT2 25, respectively. The testing apparatus according to the second embodiment is composed of the tester 39 and the test facilitation circuits 60 and 70.

As shown in FIG. 2, the DUT1 15 has two input/output-dedicated terminals G-1 and H-1, which are connected to respective 3-state buffers 61 and 63 of the test facilitation circuit 60. The DUT2 25 has two input/output-dedicated terminals G-2 and H-2, which are connected to respective 3-state buffers 71 and 73 of the test facilitation circuit 70.

On the other hand, as shown in FIG. 2, the tester 39 is equipped with a driver (test data output driver) 31 for outputting a signal a as test data to be used for testing operation of the DUT1 15 and DUT2 25 to the 3-state buffers 61 and 71 of the respective test facilitation circuits 60 and 70; a driver (control signal output driver) 31c for outputting, to the 3-state buffers 61 and 71, a control signal (IO control signal a-io) to be used for controlling which of the DUT1 15 and DUT2 25 the signal a should be sent to that is output from the driver 31; a driver (test data output driver) 32 for outputting a signal b as test data to be used for testing operation of the DUT1 15 and DUT2 25 to the 3-state buffers 63 and 73 of the respective test facilitation circuits 60 and 70; a driver (control signal output driver) 32c for outputting, to the 3-state buffers 63 and 73, a control signal (IO control signal b-io) to be used for controlling which of the DUT1 15 and DUT2 25 the signal b should be sent to that is output from the driver 32; a comparator 37 for receiving a judgment result j-3 of the test facilitation circuit 60; and a comparator 38 for receiving a judgment result j-4 of the test facilitation circuit 70.

If an IO control signal a-io that is supplied from the driver 31c is active, the 3-state buffer 61 passes a signal a coming from the driver 31 to the input/output-dedicated terminal G-1 of the DUT1 15. On the other hand, if the IO control signal a-io is not active, the 3-state buffer 61 does not pass the signal a to the input/output-dedicated terminal G-1 of the DUT1 15. As a result, output data that is output from the input/output-dedicated terminal G-1 can be supplied to an exclusive OR circuit 62 of the test facilitation circuit 60. If an IO control signal b-io that is supplied from the driver 32c is active, the 3-state buffer 63 passes a signal b coming from the driver 32 to the input/output-dedicated terminal H-1 of the DUT1 15. On the other hand, if the IO control signal b-io is not active, the 3-state buffer 63 does not pass the signal b to the input/output-dedicated terminal H-1 of the DUT1 15. As a result, output data that is output from the input/output-dedicated terminal H-1 can be supplied to an exclusive OR circuit 64 of the test facilitation circuit 60.

A similar operation is performed for the DUT2 25. If an IO control signal a-io that is supplied from the driver 31c is active, the 3-state buffer 71 passes a signal a coming from the driver 31 to the input/output-dedicated terminal G-2 of the DUT2 25. On the other hand, if the IO control signal a-io is not active, the 3-state buffer 71 does not pass the signal a to the input/output-dedicated terminal G-2 of the DUT2 25. As a result, output data that is output from the input/output-dedicated terminal G-2 can be supplied to an exclusive OR circuit 72 of the test facilitation circuit 70. If an IO control signal b-io that is supplied from the driver 32c is active, the 3-state buffer 73 passes a signal b coming from the driver 32 to the input/output-dedicated terminal H-2 of the DUT2 25. On the other hand, if the IO control signal b-io is not active, the 3-state buffer 73 does not pass the signal b to the input/output-dedicated terminal H-2 of the DUT2 25. As a result, output data that is output from the input/output-dedicated terminal H-2 can be supplied to an exclusive OR circuit 74 of the test facilitation circuit 70.

The test facilitation circuit 60 is a circuit for comparing output data of the DUT1 15 with expectation data that are supplied from the tester 39. As shown in FIG. 2, the test facilitation circuit 60 has the above-mentioned 3-state buffers 61 and 63 and exclusive OR circuits 62 and 64. The test facilitation circuit 60 further has OR circuits 65 and 66. The OR circuit 65 ORs a negated output of the exclusive OR circuit 62 and an IO control signal a-io that is supplied from the driver 31c and the OR circuit 66 ORs a negated output of the exclusive OR circuit 64 and an IO control signal b-io that is supplied form the driver 32c if neither of the IO control signal a-io and the IO control signal b-io is active. An AND circuit 67 ANDs outputs of the OR circuits 65 and 66. An output of the AND circuit 67, which is supplied to the comparator 37 of the tester 39, is a judgment result (judgment result j-3) of the test facilitation circuit 60 that indicates whether the DUT1 15 is good or no good.

Similarly, the test facilitation circuit 70 has the above-mentioned 3-state buffers 71 and 73 and exclusive OR circuits 72 and 74. The test facilitation circuit 70 further has OR circuits 75 and 76. The OR circuit 75 ORs a negated output of the exclusive OR circuit 72 and an IO control signal a-io that is supplied from the driver 31c and the OR circuit 76 ORs a negated output of the exclusive OR circuit 74 and an IO control signal b-io that is supplied form the driver 32c if neither of the IO control signal a-io and the IO control signal b-io is active. An AND circuit 77 ANDs outputs of the OR circuits 75 and 76. An output of the AND circuit 77, which is supplied to the comparator 38 of the tester 30, is a judgment result (judgment result j-4) of the test facilitation circuit 70 that indicates whether the DUT2 25 is good or no good.

Next, functions of the testing apparatus including the test facilitation circuits 60 and 70 and the tester 39 will be described. Signals (output data) that are output from the input/output-dedicated terminals G-1 and H-1 of the DUT1 15 are represented by logical variables G1 and H1, respectively, and control signals that are output from the drivers 31c and 32c of the tester 39 are represented by Ca and Cb, respectively. Logical expressions of the outputs of the exclusive OR circuits 65 and 66 are as follows:

[Formula 4]

(Output of OR circuit 65)=\overline{G1⊕a}+Ca

(Output of OR circuit 66)=\overline{H1⊕b}+Cb

where symbol “+” means OR.

Therefore, the output (judgment result j-3) of the AND circuit 67 is given by the following Equation (3):

[Formula 5]

(Output (judgment result j-3) of AND circuit 67)=(\overline{G1⊕a}+Ca)·(\overline{H1⊕b}+Cb) (3)

If neither of the control signals Ca and Cb is active (Ca=Cb=0) and if the output data of the DUT1 15 coincide with the corresponding expectation data that are output from the tester 39 (G1=a and H1=b), the AND circuit 67 has an output (judgment result j-3) that is given by the following Equation (4):

[Formula 6]

(Output (judgment result j-3) of AND circuit 67)=(0+0)·(0+0)=1·1=1 (4)

Therefore, if output data of the DUT1 15 coincide with corresponding expectation data that are output from the tester 39, a judgment result j-3 that is equal to 1 is obtained. In other words, if the judgment result j-3 is not equal to 1, one can recognize that a certain failure has occurred in the DUT1 15. The judgment result j-4 of the test facilitation circuit 70 is similar to the judgment result j-3 of the test facilitation circuit 60 and hence will not be described.

As described above, according to the second embodiment, the testing apparatus (i.e., the test facilitation circuits 60 and 70 and the tester 39) is configured as shown in FIG. 2 and expectation data are output from the tester 39, whereby the pins of the tester 39 corresponding to the input/output-dedicated terminals of the DUT1 15 and DUT2 25, that is, the pins of the drivers 31 and 32, can be shared by the DUT1 15 and DUT2 25. Even if the number of DUTs is increased to three or more, the existing pins of the tester 39 corresponding to the input/output-dedicated terminals of the DUT1 15 and DUT2 25, that is, the pins of the drivers 31 and 32, can still serve for the input/output-dedicated terminals of new DUTs. Therefore, to increase the simultaneous measurement number L (L=2 in FIG. 2), it is not necessary to increase the number of pins of the tester 39 with the number K of input/output-dedicated terminals of each DUT (K=2 in FIG. 2) as a proportionality constant.

Third Embodiment

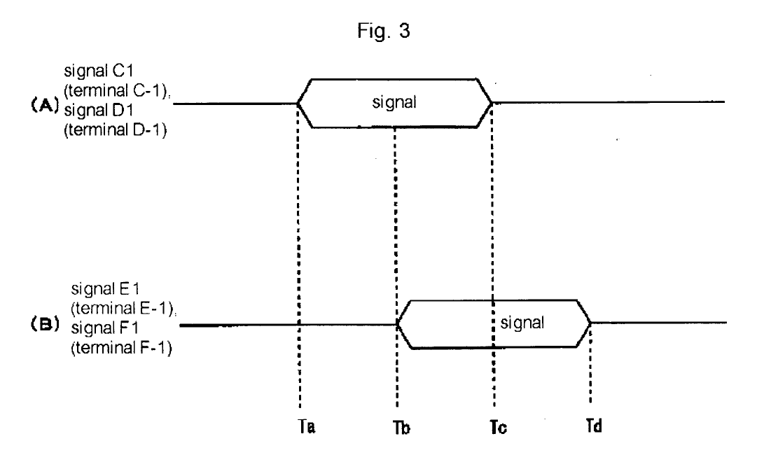

A third embodiment of the invention is directed to a case that a signal is output from each of the output-dedicated terminals C-1 to F-1 of the DUT1 10 shown in FIG. 1, for example, with timing (strobe timing) that depends on the output-dedicated terminal. FIG. 3 is a timing chart showing with what strobe timing signals are output according to the third embodiment. For convenience of description, it is assumed that signals C1 and D1 are output from the respective output-dedicated terminal C-1 and D-1 with the same timing as shown in FIG. 3A and that signals E1 and F1 are output from the respective output-dedicated terminal E-1 and F-1 with the same timing as shown in FIG. 3B. The signals C1-F1 are divided into the two groups just for convenience of description and they can naturally be divided into three groups. Although the following description will be directed to the DUT1 10 of the first embodiment, similar operation is performed for each of the DUT2 20, the DUT1 15 and DUT2 25 of the second embodiment, and like DUTs.

As shown in FIG. 3A, in the group of signals C1 and D1, a signal (e.g., 8-bit data) is output from time Ta to time Tc. On the other hand, as shown in FIG. 3B, in the group of signals E1 and F1, a signal is output from time Tb to time Td. The signals are input to the corresponding ones of the exclusive OR circuits 41-44 and the AND circuit 45 outputs a judgment result j-1. It is more practical to make a judgment with strobe timing of each group.

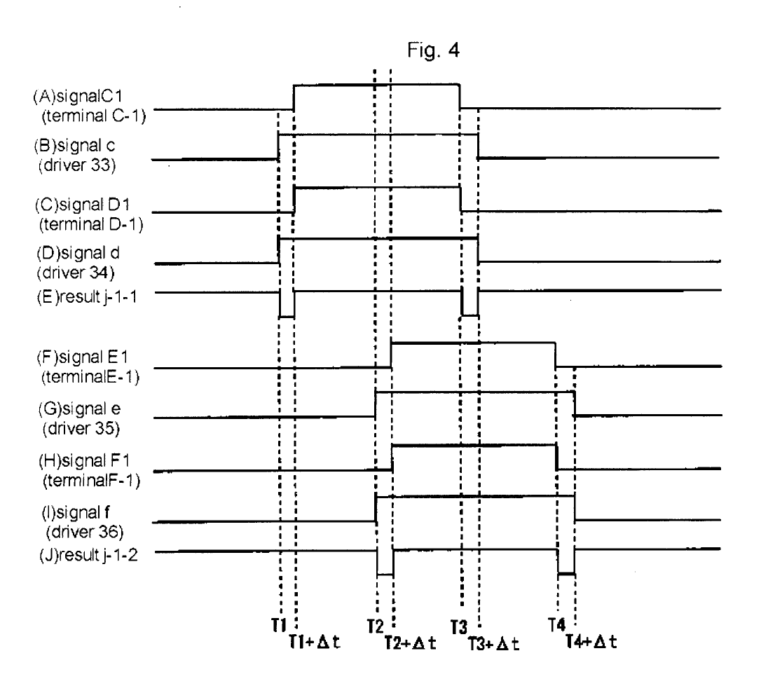

Next, a description will be made of timing between signals C1 to F1 that are output from the output-dedicated terminal C-1 to F-1 and signals c to f that are output from the drivers 33-36. FIG. 4 is a timing chart showing timing between a signal that is output from each of the output-dedicated terminal C-1 to F-1 and a signal that is output from the corresponding one of the drivers 33-36. FIG. 4A shows a signal C1 that is output from the output-dedicated terminal C-1 and FIG. 4B shows a signal c that is output from the driver 33. FIG. 4C shows a signal D1 that is output from the output-dedicated terminal D-1 and FIG. 4D shows a signal d that is output from the driver 34. FIG. 4E shows a judgment result j-1-1 only for the group of signals C1 and D1. Specifically, first, the negation of the exclusive OR of the signals C1 and c and the negation of the exclusive OR of the signals D1 and d are calculated in the same manner as in the first embodiment. Then, unlike the case of the first embodiment, the AND of only the negations of the above two exclusive ORs is calculated as a judgment result j-1-1. Similarly, FIG. 4F shows a signal E1 that is output from the output-dedicated terminal E-1 and FIG. 4G shows a signal e that is output from the driver 35. FIG. 4H shows a signal F1 that is output from the output-dedicated terminal F-1 and FIG. 4I shows a signal f that is output from the driver 36. FIG. 4J shows a judgment result j-1-2 only for the group of signals E1 and F1. Specifically, first, the negation of the exclusive OR of the signals E1 and e and the negation of the exclusive OR of the signals F1 and f are calculated in the same manner as in the first embodiment. Then, unlike the case of the first embodiment, the AND of only the negations of the above two exclusive ORs is calculated as a judgment result j-1-2.

As shown in FIGS. 4A and 4B, the signals C1 and c are different from each other in pulse width by a very short time, which measure is necessary from the viewpoint of accuracy of the circuit. More specifically, after the signal c rises at time T1, the signal C1 rises at time T1+Δt with a delay of Δt. On the other hand, after the signal c falls at time T3, the signal C1 falls at time T3+Δt with a delay of Δt. The same is true of the signals D1 and d of the same group. Therefore, during the period from T1 to T1+Δt and the period from T3 to T3+Δt, both of the negation of the exclusive OR of the signals C1 and c and the negation of the exclusive OR of the signals D1 and d are low (logical value 0) and hence, as shown in FIG. 4E, the judgment result j-1-1 (i.e., the AND of the negations of the two exclusive ORs) becomes low (logical value 0). That is, as a measure that is necessitated by the accuracy of the circuit, the judgment result j-1-1 is made low instantaneously when the signals C1 and D1 rise or fall.

Similar operation is performed for the other group. As shown in FIGS. 4F and 4G, the signals E1 and e are different from each other in pulse width by a very short time, which measure is necessary from the viewpoint of accuracy of the circuit. More specifically, after the signal e rises at time T2, the signal E1 rises at time T2+Δt with a delay of Δt. On the other hand, after the signal E1 falls at time T4, the signal e falls at time T4+Δt with a delay of Δt. The same is true of the signals F1 and f of the same group. Therefore, during the period from T2 to T2+Δt and the period from T4 to T4+Δt, both of the negation of the exclusive OR of the signals E1 and e and the negation of the exclusive OR of the signals F1 and f are low (logical value 0) and hence, as shown in FIG. 4J, the judgment result j-1-2 (i.e., the AND of the negations of the two exclusive ORs) becomes low (logical value 0). That is, as a measure that is necessitated by the accuracy of the circuit, the judgment result j-1-2 is made low instantaneously when the signals E1 and F1 rise or fall.

As shown in FIGS. 4E and 4J, in the period from T2 to T2+Δt, the judgment result j-1-1 is high (logical value 1) correctly in the group of signals C1 and D1 but varies instantaneously in the group of signals E1 and F1 because this period is a signal switching period that is necessitated by the accuracy of the circuit. Therefore, if a judgment is performed in such a manner as to involve signals of two groups that are different in strobe timing, stable judgment results may not be obtained. Involvement of such a signal switching period in a judgment can be avoided by performing a judgment for each set of signals that belong to the same group and hence have the same strobe timing.

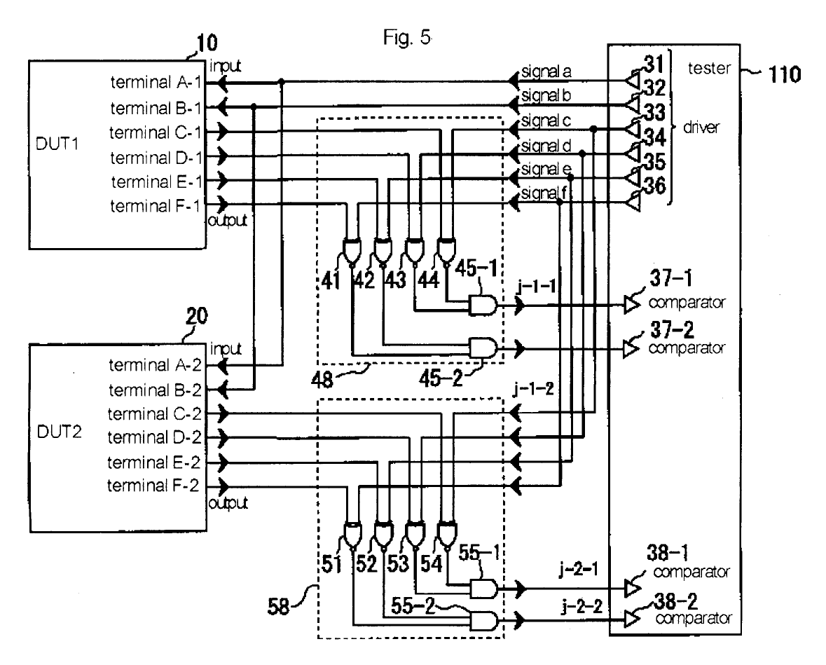

FIG. 5 shows a testing apparatus according to the third embodiment of the invention for testing devices under test (DUTs) such as digital ICs. Items in FIG. 5 that are given the same reference symbols as the corresponding items in FIG. 1 have the same functions as the latter do, and hence will not be described. The testing apparatus according to the third embodiment is different from that according to the first embodiment in the following points. In a test facilitation circuit 48, the AND of negated outputs of only the exclusive OR circuits 44 and 43 is calculated as a judgment result j-1-1 by an AND circuit 45-1, and the AND of negated outputs of only the exclusive OR circuits 42 and 41 is calculated as a judgment result j-1-2 by an AND circuit 45-2. The judgment results j-1-1 and j-1-2 are input to respective comparators 37-1 and 37-2 of a tester 110. That is, for the DUT1 10, a judgment for the group of signals C1 and D1 that are output from the respective output-dedicated terminals C-1 and D-1 and have the same strobe timing is calculated as a judgment result j-1-1, and a judgment for the group of signals E1 and F1 that are output from the respective output-dedicated terminals E-1 and F-1 and have the same strobe timing is calculated as a judgment result j-1-2. The judgment results j-1-1 and j-1-2 are input to the separate comparators 37-1 and 37-2 of the tester 110.

Similar operation is performed in the test facilitation circuit 58. The AND of negated outputs of only the exclusive OR circuits 54 and 53 is calculated as a judgment result j-2-1 by an AND circuit 55-1, and the AND of negated outputs of only the exclusive OR circuits 52 and 51 is calculated as a judgment result j-2-2 by an AND circuit 55-2. The judgment results j-2-1 and j-2-2 are input to respective comparators 38-1 and 38-2 of the tester 110. That is, also for the DUT2 20, a judgment for the group of signals C2 and D2 that are output from the respective output-dedicated terminals C-2 and D-2 and have the same strobe timing is calculated as a judgment result j-2-1, and a judgment for the group of signals E2 and F2 that are output from the respective output-dedicated terminals E-2 and F-2 and have the same strobe timing is calculated as a judgment result j-2-2. The judgment results j-2-1 and j-2-2 are input to the separate comparators 38-1 and 38-2 of the tester 110.

As described above, where two groups having the same strobe timing exist for one DUT, two judgments are performed for the one DUT and hence the tester 110 should be provided with two comparators for the one DUT. In general, where n groups having the same strobe timing exist for one DUT, n judgments are performed for the one DUT and hence the tester 110 should be provided with n comparators for the one DUT. Therefore, where L DUTs exist, the tester 110 should be provided with n×L comparators. Where DUTs of the same type are to be tested, the n value is the same for the DUTs and hence the number of comparators that the tester 110 should have becomes L, 2L, 3L, etc. However, where DUTs of different types are to be tested, the n value depends on the DUT. In this case, the number of comparators that the tester 110 should have becomes L, L+1 (only one DUT has two groups of signals), L+2 (only one DUT has three groups of signals or two DUTs have two groups of signals), L+3, etc. It is concluded that in general the tester 110 of the testing apparatus according to the third embodiment should have a plurality of drivers 31 etc. for outputting test data a etc. and at least L (preferably n×L) comparators 37 etc. for receiving judgment results for L DUTs.

Although the above description is directed to the DUT1 10 of the first embodiment, similar operation is performed for the DUT1 15 of the second embodiment. In the latter case, each of the DUT1 15 etc. can have input/output-dedicated terminals that are divided into n groups in which signals of the same group have the same strobe timing, in the same manner as described above. Therefore, in general, the tester 39 of the testing apparatus according to the second embodiment can have a plurality of drivers 31 etc. for outputting test data a etc., a plurality of drivers 31c etc. for outputting control signals Ca etc. to be used for controlling the test data a etc. in such a manner that the control signals Ca etc. accompany the test data a etc., and at least L (preferably n×L) comparators 37 etc. for receiving judgment results for L DUTs.

The above testing apparatus can provide the same advantages as in the first and second embodiment: even if the number of DUTs is increased to three or more, the existing pins of the tester 110 corresponding to the output-dedicated terminals of the DUT1 10 and DUT2 20, that is, the pins of the drivers 31-36, can still serve for the output-dedicated terminals of new DUTs. Therefore, to increase the simultaneous measurement number L (L=2 in FIG. 5), it is not necessary to increase the number of pins of the tester 110 with the number K of output-dedicated terminals of each DUT (K=4 in FIG. 5) as a proportionality constant.

Fourth Embodiment

The above-described test facilitation circuits 40, 50, 60, 70, 48, and 58 and like ones can be used for simultaneous measurements on a plurality of digital ICs under test in testing burn-in or wafer-level burn-in.

The features and advantages of the present invention may be summarized as follows.

As described above, the testing apparatus is configured by using the test facilitation circuits 40 and 50 and the tester 30, for example, and expectation data are output from the tester 30, for example, whereby the pins of the tester 30, for example, corresponding to the output-dedicated terminals of the DUT1 10 and DUT2 20, for example, that is, the pins of the drivers 33-36, for example, can be shared by the DUT1 10 and DUT2 20, for example. Even if the number of DUTs is increased to three or more, the existing pins of the tester 30, for example, corresponding to the output-dedicated terminals of the DUT1 10 and DUT2 20, for example, that is, the pins of the drivers 33-36, for example, can still serve for the output-dedicated terminals of new DUTs. Therefore, to increase the simultaneous measurement number L (L=2 in FIG. 1), it is not necessary to increase the number of pins of the tester 30, for example, with the number K of output-dedicated terminals of each DUT (K=4 in FIG. 1) as a proportionality constant.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-171866, filed on Jun. 12, 2002 including specification, claims, drawings and summary, on which the Convention priority of the present application is based, are incorporated herein by reference in its entirety.

1. A test facilitation circuit of a testing apparatus for simultaneously testing L digital ICs each having K output terminals, L being greater than or equal to 2 and K being greater than or equal to 1, wherein:
the test facilitation circuit receives K output data that are output from the K respective output terminals of each of the L digital ICs and K expectation data that are output from K respective drivers of a tester that has the K drivers and L comparators, and the test facilitation circuit supplies the L comparators with L judgment results for the output data of the L digital ICs respectively.

2. The test facilitation circuit according to claim 1, comprising L units that correspond to the L respective digital ICs, each of the L units comprising:
K exclusive OR circuits for calculating K exclusive ORs of the K output data from a corresponding one of the digital ICs and the K expectation data, respectively; and
an AND circuit for receiving negated outputs of the K respective exclusive OR circuits and outputting a corresponding one of the L judgment results.

3. A test facilitation circuit of a testing apparatus for simultaneously testing L digital ICs each having a plurality of input/output terminals, L being greater than or equal to 2, wherein:
the test facilitation circuit supplies L judgment results for output data of the L digital ICs to L comparators of a tester, respectively, the tester having the L comparators, test data output drivers for outputting respective test data, and control signal output drivers for outputting respective control signals to be used for controlling the test data in such a manner that the control signals accompany the respective test data;
the test facilitation circuit comprises L units that correspond to the L respective digital ICs;
when the control signals are active, each of the L units supplies the input/output terminals of the corresponding one of the digital ICs with the test data that are output from the test data output drivers of the tester; and
when the control signals are not active, each of the L units receives output data that are output from the input/output terminals of the corresponding one of the digital ICs, the test data that are output from the test data output drivers of the tester and the control signals that are output from the control signal output drivers of the tester, and supplies a corresponding one of the L comparators with a judgment result for the output data of the corresponding one of the digital ICs.

4. The test facilitation circuit according to claim 3, wherein each of the L units comprises:
a first 3-state buffer for supplying first test data that is output from the tester to a first input/output terminal of the corresponding one of the digital ICs, when a first control signal that is output from the tester so as to accompany the first test data is active;
a first exclusive OR circuit for calculating an exclusive OR of first output data that is output from the first input/output terminal and the first test data that is output from the tester, when the first control signal is not active;
a first OR circuit for ORing an negated output of the first exclusive OR circuit and the first control signal that is not active;
a second 3-state buffer for supplying second test data that is output from the tester to a second input/output terminal of the corresponding of the digital ICs, when a second control signal that is output from the tester so as to accompany the second test data is active;
a second exclusive OR circuit for calculating an exclusive OR of second output data that is output from the second input/output terminal and the second test data that is output from the tester, when the second control signal is not active;
a second OR circuit for ORing an negated output of the second exclusive OR circuit and the second control signal that is not active; and
an AND circuit for ANDing outputs of the first and second OR circuits and outputting an AND result as a judgment result.

5. The test facilitation circuit according to claim 1, wherein the test facilitation circuit is used for simultaneous tests on a plurality of digital ICs in testing burn-in or wafer-level burn-in.
